(19) United States
(12) Patent Application Publication
(10) Pub. No.: US 2010/0120256 A1
(43) Pub. Date: May 13, 2010

(54) METHOD FOR REMOVING ETCHING RESIDUES FROM SEMICONDUCTOR COMPONENTS

(75) Inventors: Berthold Ferstl, Bensheim (DE); Andreas Kuehner, Darmstadt (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/598,605

(22) PCT Filed: May 9, 2008
(86) PCT No.: PCT/EP08/55737

§ 371 Date: Nov. 3, 2009

(30) Foreign Application Priority Data
May 14, 2007 (EP) 07108145.9

(51) Int. Cl. H01L 21/3065; H01L 21/308; H01L 21/3105

(52) U.S. Cl. 438/704; 438/745; 257/E21.218; 257/E21.219; 257/E21.231

(57) ABSTRACT

A method for cleaning structured surfaces of semiconductor components to remove photoresist and etching residues after the etching of the surface, comprising: a) removal of the photoresist, b) treatment of the surface with an acidic aqueous solution comprising one or more acids and one or more oxidizing agents, c) treatment of the surface with an alkaline aqueous solution and d) washing of the surface with demineralized water, the steps a), b) and c) being effected before step d).

The present invention relates to methods for cleaning structured surfaces of semiconductor components to remove photoresist and etching residues after the etching of the surface.

Back-end-of-line (BEOL) metallizations (conductor tracks) on semiconductor components substantially comprise an aluminum layer applied by sputtering and having an optional proportion of up to 5% of copper and/or silicon. The conductor tracks are produced photolithographically. An SiO₂ layer between the individual metal layers, which are connected perpendicularly by via studs (tungsten or aluminum) serves as a dielectric. The structures (conductor tracks and via studs) are produced by plasma etching. The conductor tracks are usually produced by the following process steps:

1. Full-area sputtering of the following layers onto an SiO₂ insulation layer:
a) Thin Ti/TiN layer as a diffusion barrier,
b) AlCu metallization layer and
c) Thin Ti/TiN layer as an anti-reflective coating (ARC);

2. Application of the positive photoresist by spin coating with subsequent exposure and development of the structures;

3. Etching of the layers by plasma etching with the use of halogen-containing etching gases;

4. Removal of the photoresist;

5. Removal of the etching residues (post etch residues, PER) by means of a wet process;

6. Washing with water (spray process).

The structuring of SiO₂ layers takes place in a similar manner, an SiO₂ layer being structured in step 1 instead of the Al(Si/Cu) layer.

Etching residues, the so-called post etch residues (PER), form during step 3, to a particularly pronounced extent on the side walls of the aluminum conductor tracks. These, like the remaining photoresist, have to be removed completely before the further processing during steps 4 and 6.

The removal of the PER is usually effected by means of wet cleaning methods. Organic solvents which comprise complexing agents and water can be used here. The products most frequently used at present are amine-containing organic solvent mixtures which may optionally comprise corrosion inhibitors, complexing agents and surfactants. In addition, for example, WO 2005/098920 discloses an aqueous acidic solution comprising an organic acid and an oxidizing agent.

In addition, alkaline aqueous solutions were also used for removing PER. Thus, a solution comprising tetramethylammonium hydroxide and special metal halides is described, for example in WO 2005/043245.

What is disadvantageous about the cleaning methods described is that in particular stubborn etching residues are removed from the surface only to an insufficient extent under unfavorable etching conditions or an undesired attack on the semiconductor structures takes place.

It is an object of the present invention, compared with the abovementioned prior art, to provide a method of the type mentioned at the outset by means of which even stubborn etching residues can be reliably removed without attacking the structures of the semiconductor component.

The present invention is based on the discovery that an acidic wet cleaning step in combination with an alkaline wet cleaning step displays a considerably improved cleaning effect or leads to a shortening of the cleaning time.

The present invention therefore relates to a method for cleaning structured surfaces of semiconductor components to remove photoresist and etching residues after the etching of the surface, comprising:
a) removal of the photoresist,
b) treatment of the surface with an acidic aqueous solution comprising one or more acids and one or more oxidizing agents,
c) treatment with an alkaline aqueous solution and
d) washing with demineralized water,
   the steps a), b) and c) being effected before step d).

Surprisingly, it is possible, with a combination of acidic and alkaline cleaning steps, to achieve substantially improved cleaning results in a shorter cleaning time (stripping time) compared with methods known to date and comprising acidic treatment. Advantageously, the etching residues (PER) can be very reliably and completely removed during the cleaning process, neither the metallized conductor tracks nor the other surfaces, such as, for example, of Ti, TiN, or SiO₂, being noticeably attacked.

A further advantage of the present method is the increased range of applicability and flexibility. The duration and sequence of individual steps can be adapted in a controlled manner to the substrate. The method is distinguished in particular by its simple and flexible handling properties with the use of spray tools.

In an advantageous development of the method according to the invention, the alkaline aqueous solution in step b) comprises from 75 to 99.99% by weight of water, 0-10% by weight of one or more corrosion inhibitors and from 0.01 to 10% by weight of a metal-free base. Particularly preferred bases are quaternary ammonium hydroxides.

In a further advantageous development, the alkaline aqueous solution is substantially free of metal compounds.

Furthermore, it is advantageous if the alkaline aqueous solution is substantially free of oxidizing agents.

In an advantageous development of the method according to the invention, the acidic aqueous solution comprises an organic acid, in particular an organic acid from the group consisting of the hydroxycarboxylic acids and/or the group consisting of the mono-, di- and tricarboxylic acids. The organic acid is particularly preferably selected from the group consisting of glycolic acid, lactic acid, hydroxybutyric acid, glyceric acid, malic acid, tartaric acid, citric acid, malonic acid, succinic acid, glutaric acid and maleic acid.

The oxidizing agent is preferably selected from the group consisting of hydrogen peroxide and ammonium peroxodisulfate.

It is furthermore advantageous if the acidic aqueous solution comprises at least one anionic and/or one nonionic surfactant in an amount of from 1 ppm to 1%, based on the total weight, since this promotes the wetting of the surface.

The treatment with the acidic aqueous solution and with the alkaline aqueous solution can be carried out in any desired sequence. The same applies to the removal of the photoresist. However, it is preferable to carry out the steps b) and c) and d) in a said sequence and to effect step a) before step d). It is particularly preferable to carry out the method in the sequence a), b), c) and d).

In a particularly preferred embodiment, the method comprises the steps:
a) removal of the photoresist by means of an oxygen plasma,
b) treatment of the surface with an acidic aqueous solution comprising one or more acids and one or more oxidizing agents,
c) treatment of the surface with an alkaline aqueous solution,
d) washing of the surface with demineralized water and
e) drying with inert gas,
   in said sequence. Alternatively, step b) can also be effected before, or several times in alternation with, step c), if appropriate with an optional wash step d) between the steps b) and c).

The method according to the invention can be used in particular for the production of semiconductor components. The present invention therefore furthermore relates to a method for the production of a semiconductor component, comprising the cleaning method according to the invention.

Below, the individual steps of the method according to the invention are described in detail.

In step a) of the method according to the invention, the photoresist is removed. This can be effected in the dry state, for example by means of an oxygen plasma, or by a wet chemical method, for example by using cleaning solutions, without being limited thereto. Methods of this type are generally known. This step can be effected directly after the etching process but also after the step b) or c). It is preferable to carry out the steps a), b), c) and up to d) in this sequence.

In step b), the surface is treated with an acidic aqueous solution comprising one or more acids and one or more oxidizing agents. Here, the major part of the etching residues is removed. The treatment is usually effected for from 10 seconds to 1 hour, preferably from 1 minute to 30 minutes, particularly preferably from 5 minutes to 20 minutes.

The procedure may be effected at room temperature but also preferably at elevated temperature up to about 90° C. The procedure is preferably effected at from 30° C. to 80° C., particularly preferably at from 40° C. to 75° C.

In the context of the present invention, a solution having a pH of about less than 5, preferably less than 4, particularly preferably less than 3, is acidic. In principle, all customary inorganic and/or organic acids, individually or in combination, can be used in step b). Sulfuric acid or citric acid may be mentioned by way of example here.

Preferred acidic solutions for carrying out step b) are aqueous solutions which comprise at least one organic acid. Acids selected from the group consisting of the hydroxycarboxylic acids and/or the di- and tricarboxylic acids are particularly preferred. Suitable hydroxycarboxylic acids are glycolic acid, lactic acid, hydroxybutyric acid, glyceric acid, malic acid, tartaric acid and citric acid. Suitable dicarboxylic acids are malonic acid, succinic acid, glutaric acid and maleic acid, individually or in combination.

In addition to at least one, preferably organic, acid, at least one oxidizing agent is present in the acidic solution. In principle, all oxidizing agents which can oxidatively degrade the etching and photoresist residues without excessively attacking the semiconductor structure can be used as suitable oxidizing agents. Oxidizing agents free of metal ions, such as hydrogen peroxide and ammonium peroxodisulfate, are preferred and may be present individually or in combination in the acidic solutions. Acidic solutions which comprise no HF or HF-generating compounds are furthermore preferred.

In addition, a very wide range of additives for improving the cleaning effect and for protecting the surfaces which are not to be attacked may be present in the acidic solutions. Thus, it has proven advantageous if corrosion inhibitors are present in the solutions. Imidazoline compounds are preferably added as corrosion inhibitors to solutions which are intended for the treatment of wafer surfaces which have, for example, metallizations comprising tungsten and aluminum. Suitable imidazoline compounds are, for example, benzimidazoles (alkyl-substituted imidazolines or 1,2-dialkylimidazolines), aminobenzimidazoles and 2-alkylbenzimidazoles. Particularly good cleaning results are obtained with solutions which comprise oleic acid hydroxyethylimidazoline as a corrosion inhibitor.

For promoting the cleaning effect and for protecting the wafer surfaces, an aprotic polar solvent may be added to the solution. Suitable aprotic polar solvents for this purpose are N-methylpyrrolidone (NMP), ethylene glycol, propylene glycol, dimethyl sulfoxide (DMSO) and 1-methoxy-2-propyl acetate (PGMEA). These organic solvents may be present in the solution individually or as a mixture.

Furthermore, it has proven advantageous if surface-active substances are additionally present in the cleaning solution. Anionic surfactants have proven to be suitable surface-active substances. Particularly suitable surfactants are those selected from the group consisting of the aliphatic carboxylic acids and/or from the group consisting of the alkylbenzenesulfonic acids. Suitable aliphatic carboxylic acids are, for example, heptanoic acid and octanoic acid. Inter alia, dodecylbenzenesulfonic acid can be used as the alkylbenzenesulfonic acids.

Anionic surfactants can be used together with nonionic surfactants or can replace them. Nonionic surfactants which may be used are those from the group consisting of the alkyl oxyalkylates and/or of the alkylphenol oxyethylates. Alkyl oxyalkylates suitable for this purpose are, for example, fatty alcohol alkoxylates. Inter alia, octylphenyl oxyethylate can be added as alkylphenol oxyethylates. Furthermore, sorbitan compounds, such as polyoxyethylene sorbitan fatty acid esters, are suitable as surfactants in the solutions according to the invention. These include surfactants such as, for example, products available commercially under the name Tween®.

The acidic cleaning solutions which can be used in step b) preferably have compositions as shown in the table below:

TABLE 1

| | 1 | 2 | 3 | 4 | 5 | 6 | 7 | 8 |
|---|---|---|---|---|---|---|---|---|
| Organic acid | x | x | x | X | x | x | x | X |
| Oxidizing agent | x | x | x | X | x | x | x | X |
| Solvent | | x | | X | | | x | X |
| Surfactant | | | x | X | | x | x | |
| Corrosion inhibitor | | | | | x | x | x | X |

The acidic cleaning solutions preferably comprise the following individual components:
organic acid from the group consisting of the hydroxycarboxylic acids and/or di- and tricarboxylic acids in an amount of from 0.1 to 30%
oxidizing agent in an amount of from 0.1 to 10%
corrosion inhibitors, for example from the group consisting of the imidazoline compounds, for tungsten and aluminum in an amount of from 1 ppm to 1%
aprotic polar solvent in an amount of from 0 to 10%
anionic surfactant from the group consisting of the aliphatic carboxylic acids and of the alkylbenzenesulfonic acids in an amount of from 1 ppm to 1% and/or
nonionic surfactant from the group consisting of the alkyl oxyalkylates, alkylphenol oxyethylates and sorbitan compounds in an amount of from 1 ppm to 1%.

In suitable cleaning solutions having improved properties, the components may therefore preferably be present in the following amounts:

| | |
|---|---|
| di-, tri- or hydroxycarboxylic acid | from 0.1 to 30% |
| hydrogen peroxide | from 0.1 to 30% |
| corrosion inhibitor | from 1 ppm to 1% |
| anionic or nonionic surfactant | from 1 ppm to 1% |

In a particularly preferred embodiment, solutions which, in addition to water, substantially comprise said components are used.

In step c) of the method according to the invention, the surface of the semiconductor component is treated with an alkaline aqueous solution. Strongly adhering etching residues are also reliably removed thereby. Step c) preferably follows step b), if appropriate after washing with demineralized water. However, it is also possible to carry out step c) before step b).

The treatment with alkaline aqueous solution is usually effected for from 1 second to 1 hour, preferably from 10 seconds to 20 minutes, particularly preferably from 15 seconds to 10 minutes. In an advantageous development of the present invention, step c) is shorter than step b). It is particularly preferable if step c) is shorter than step b) by a factor of 2, in particular a factor of 3.

The procedure can be effected at room temperature but also at slightly reduced or elevated temperature. The procedure is preferably effected at from 10° C. to 40° C., particularly preferably at from 20° C. to 30° C.

In the context of the present invention, a solution having a pH above about 8 is alkaline or basic. The pH of the alkaline solution when carrying out step c) is preferably above 9, particularly preferably above 10.

In principle, all water-soluble bases are suitable for the method according to the invention, bases free of metal ions, such as ammonium hydroxides, being preferred.

Preferred basic solutions for carrying out step c) are aqueous solutions which comprise at least one organic base, such as quaternary ammonium hydroxides or alkanolamines. Organic bases selected from the group consisting of the quaternary ammonium hydroxides, such as tetraalkylammonium hydroxides whose alkyl groups comprise 1 to 4 carbon atoms, which may be optionally substituted, are particularly preferred. Suitable tetraalkylammonium hydroxides are, for example, tetramethylammonium hydroxide and trimethyl-2-hydroxyethylammoniumhydroxide, which may be present individually or in combination in the solutions.

In addition to at least one organic base, if appropriate at least one oxidizing agent may be present in the basic solution. Oxidizing agents which may be used are in principle all known oxidizing agents, but hydrogen peroxide and ammonium peroxodisulfate are preferred and may be present individually or in combination in the solutions. The oxidizing agents can be used in general in concentrations of from 0 to 30% by weight, preferably from 0 to 10% by weight. Particularly preferably, no oxidizing agents are used in step c).

In addition, a very wide range of additives for improving the cleaning effect and for protecting the surfaces which are not to be attacked may be present in the basic solutions. Thus, it has proven advantageous if chelating agents and/or corrosion inhibitors are present in the solutions. For the treatment of wafer surfaces which have, for example, metallizations comprising copper and aluminum or tungsten and aluminium, polyhydroxy compounds are preferably added as corrosion inhibitors. Suitable polyhydroxy compounds are, for example, glycerol, mannitol and/or other sugar alcohols.

Furthermore, a nonionic, amphoteric, anionic or cationic wetting agent may be present in the basic cleaning solution, for reducing the surface tension and for better wetting of the surfaces to be cleaned. Suitable wetting agents are generally known and are described, for example, in WO 2005/043245.

It may furthermore be advantageous to add buffer mixtures to the acidic or alkaline solutions in order to stabilize the pH at the specified value.

The alkaline cleaning solutions which can be used in step c) preferably have compositions as shown in the table below:

TABLE 2

| | 1 | 2 | 3 | 4 | 5 | 6 | 7 | 8 |
|---|---|---|---|---|---|---|---|---|
| Organic base | x | x | X | x | x | x | x | x |
| Oxidizing agent | | x | | x | | x | x | |
| Solvent | | | X | x | | | | |
| Surfactant | | | | | x | | x | |
| Corrosion inhibitor | | | | | | x | x | x |

The basic cleaning solutions preferably comprise the following components, which can be used independently of one another:
organic bases from the group consisting of the quaternary ammonium hydroxides and/or alkanolamines in an amount of from about 0.01 to about 10%
oxidizing agents in an amount of from 0 to about 10%
corrosion inhibitors, for example from the group consisting of the polyalcohols, in an amount of from 1 ppm to 1%
aprotic polar solvents in an amount of from 0 to about 10% and/or
a surfactant in an amount of from about 1 ppm to about 1%

In suitable cleaning solutions having improved properties, the components should therefore preferably be present approximately in the following amounts:

| | |
|---|---|
| quaternary ammonium hydroxides | from 0.01 to 5% |
| hydrogen peroxide | from 0 to 1% |
| corrosion inhibitor | from 1 ppm to 1% |
| nonionic or cationic surfactant | from 1 ppm to 1% |

Particularly good cleaning results can be achieved with compositions which, in addition to water, comprise the following components:

| | |
|---|---|
| tetraalkylammonium hydroxides | from 0.05 to 2% |
| corrosion inhibitor | from 1 to 10% |
| wetting agent | from 100 to 1000 ppm |

Solutions in which, for example, said components are present in the following amounts are particularly suitable:

| | |
|---|---|
| tetramethylammonium hydroxide | from 0.05 to 1% |
| corrosion inhibitor | from 1 to 10% |

In a particularly preferred embodiment, solutions which substantially comprise said components in addition to water are used.

Finally, the surface of the semiconductor component is washed with demineralized water in step d) in order to remove the dissolved residues and solvents. In this case, demineralized is intended to mean merely that no undesired contamination with impurities, such as, for example, heavy metal ions or particles, is caused by the water. The required purity is to be specified appropriately in line with the use of the semiconductor component. Water of suitable purity is commercially available and is frequently also offered under the designation ultra pure water.

Depending on the further processing, the semiconductor component can also be dried. This can be effected, for example, in a nitrogen stream.

The method according to the invention can be used on spray units as well as in tank processors. In particular, it is advantageous if the steps b) and c) are carried out in the same apparatus.

Advantageously, the solutions used in steps b) and c) are stable compositions which show no decomposition even after a relatively long storage time. A not inconsiderable advantage of the compositions is their environmental compatibility, so that they can be easily disposed of. If desired they can also be recycled.

Surprisingly, it is possible with the two-stage cleaning method according to the invention, in a comparable or shorter cleaning time (stripping time), particularly in the case of strong topography and associated over etching of regions, to achieve further improved cleaning results compared with the one-stage methods known to date. Even under unfavorable circumstances, the etching residues (PER) can be completely removed during the cleaning process, but neither the metallized conductor tracks nor other surfaces, such as, for example, TiN, or SiO₂, are noticeably attacked.

All documents cited are hereby incorporated by reference into the present patent application. All stated proportions (stated percentages, ppm, etc.) refer to the weight based on the total weight of the mixture, unless stated to the contrary.

The following examples explain the present invention without limiting it thereto.

### EXAMPLES

Tests were carried out on wafers which had etching residues which were particularly difficult to remove, owing to overetching and ageing for several days.

### Example 1

First, the photoresist was removed with the aid of an oxygen plasma.

The etching residues were removed in two successive steps. First, the wafer was treated for 20 minutes at 60° C. with an acidic aqueous cleaning solution by the immersion method (the spray method gives comparable results). The acidic cleaning solution used corresponded to that which was used in example 2 of WO2005/098920.

The wafer was then treated in the same apparatus at 22° C. for 30 seconds with an alkaline aqueous solution which had the following composition:

Tetramethylammonium hydroxide (TMAH) 0.2%

Mannitol 4%

Water 95.8%

Thereafter, washing was effected at 22° C. for 2 minutes with demineralized water and drying was effected for 10 minutes with nitrogen.

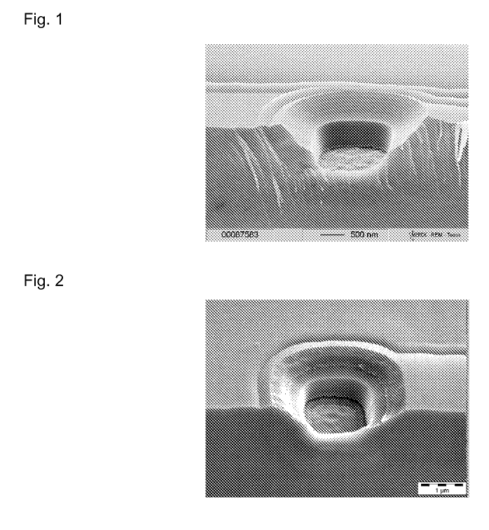

FIG. 1 shows the semiconductor component after the treatment. All etching residues were completely removed.

### Comparative Example A

The procedure was as in example 1, except that no treatment with an alkaline aqueous solution was effected. The treatment time with the acidic aqueous solution was 20 minutes at 60° C.

FIG. 2 shows the semiconductor component after the treatment. Etching residues are still present. Under these worst case conditions, the treatment according to the prior art does not result in adequate cleaning of the surface.

1. A method for cleaning semiconductor components, comprising:
a) removing a photoresist,
b) treating a surface of a semiconductor component with an acidic aqueous solution comprising at least one acid and at least one oxidizing agent,
c) treating the surface with an alkaline aqueous solution and
d) washing the surface with demineralized water, wherein a), b) and c) are effected before d).

2. The method according to claim 1, wherein the alkaline aqueous solution in c) comprises from 75 to 99.99% by weight of water, 0-10% by weight of one or more corrosion inhibitors and from 0.01 to 10% by weight of a metal-free base.

3. The method according to claim 2, wherein the metal-free base is ammonia or a quaternary ammonium hydroxide.

4. The method according to claim 2, wherein the alkaline aqueous solution is substantially free of metal compounds.

5. The method according to claim 1, wherein the alkaline aqueous solution is substantially free of the at least one oxidizing agent.

6. The method according to claim 1, wherein the alkaline aqueous solution comprises a polyhydroxy compound as a corrosion inhibitor.

7. The method according to claim 1, wherein the acidic aqueous solution comprises an organic acid selected from the group consisting of hydroxycarboxylic acid, monocarboxylic acid, dicarboxylic acid, and tricarboxylic acid.

8. The method according to claim 7, wherein the organic acid is selected from the group consisting of glycolic acid, lactic acid, hydroxybutyric acid, glyceric acid, malic acid, tartaric acid, citric acid, malonic acid, succinic acid, glutaric acid and maleic acid.

9. The method according to claim 1, wherein the at least one oxidizing agent of the acidic aqueous solution is selected from the group consisting of hydrogen peroxide and ammonium peroxodisulfate.

10. The method according to claim 1, wherein the acidic aqueous solution comprises at least one anionic or one nonionic surfactant, or a mixture thereof, in an amount of from 1 ppm to 1%, based on the total weight.

11. The method according to claim 1, wherein b), c) and d) are carried out in said sequence and a) is effected before d).

12. The method according to claim 1, further comprising:
a) removing the photoresist with an oxygen plasma,
b) treating the surface with an acidic aqueous solution comprising at least one acid and at least one oxidizing agent,
c) treating the surface with an alkaline aqueous solution,
d) washing the surface with demineralized water and
e) drying with inert gas,
in said sequence.

13. A method for the production of a semiconductor component comprising a cleaning method according to claim 1.

14. The method according to claim 2, wherein the metal-free base does not comprise metal.

15. The method according to claim 1, wherein the alkaline aqueous solution does not comprise metal.

16. The method according to claim 1, wherein the alkaline aqueous solution does not comprise an oxidizing agent.
